(19) United States
(12) Patent Application Publication
(10) Pub. No.: US 2026/0136683 A1
(43) Pub. Date: May 14, 2026

(54) Semiconductor detector device

(71) Applicant: Teknologian tutkimuskeskus VTT Oy, Espoo (FI)

(72) Inventors: Markku Kainlauri, Espoo (FI); Olli-Pekka Kilpi, Espoo (FI); Aapo Varpula, Espoo (FI); Mika Prunnila, Espoo (FI)

(21) Appl. No.: 18/696,375

(22) PCT Filed: Sep. 30, 2022
(86) PCT No.: PCT/FI2022/050651

§ 371 Date: Mar. 28, 2024

(30) Foreign Application Priority Data
Oct. 1, 2021 (FI) 20216020

(51) Int. Cl. H10F 30/223; H10F 77/1223; H10F 77/20; H10F 77/30

(52) U.S. Cl. CPC H10F 30/223; H10F 77/244; H10F 77/331; H10F 77/1223

(57) ABSTRACT

According to an example aspect of the present invention, there is provided semiconductor radiation detectors and photodetectors with a low amount of material in the radiation/photon entrance window.

### FIELD

The present invention relates to semiconductor detectors, such as radiation detectors and photodetectors.

### BACKGROUND

In an electromagnetic radiation detector, semiconductor material is generally used as an electromagnetic radiation detection layer.

A photodiode is a semiconductor device with a P-N junction that converts photons (or light) into electrical current. The P layer has an abundance of holes (positive), and the N layer has an abundance of electrons (negative). Photodiodes can be manufactured from a variety of materials including, but not limited to, Silicon, Germanium, and Indium Gallium Arsenide. Each material uses different properties for cost benefits, increased sensitivity, wavelength range, low noise levels, or even response speed.

Photodetectors may be based on different technologies, including photodiodes (PN junction, PIN junction, Schottky diode). Conventional PN junction radiation detectors and photodetectors are based on PN junctions which lie rather deep below the surface of the detector. This leaves an electrically dead layer between the entrance window and the PN junction of the detector, thereby reducing the electrical output signal of the detector via absorption of radiation signal within the dead layer. Furthermore, in conventional PN junction based detectors, the moderate or heavy doping of the top part of the PN junction increases the Auger recombination in this region giving rise to lower quantum efficiency and output signal. The signal reduction via absorption is especially detrimental in detection of UV and X-ray photons, and gamma rays. The signal reduction associated with the excess depth of the PN junction and doping (via Auger recombination) is crucial in UV detectors as UV photons have very low absorption lengths.

Shallow PN junctions, which lie very near the surface of the detector, are especially needed in detection of high energy photons (such as UV and X-ray radiation) as any photo-electrically dead layer between the entrance window and the PN junction is minimal. Induced junctions provide efficient ways to realize shallow PN junctions, and they are also efficient in detection of lower-energy photons.

Existing induced junction detectors are based on deposition of inducing surface charge on the detector surface. They rely on the properties of the surface charge, for example, its surface density and lifetime. In addition, any absorption of radiation in the inducing layer is detrimental to the detector as the absorbed signal is lost. All these features of the inducing layer are determined by the material properties of this layer, which are limited by the available materials, and deposition and post-deposition processes. Present generation methods of the charge inside the top dielectric (entrance window) of the detectors pose reliability, stability and yield issues. For example, the publication of Dönsberg et al.: “Predictable quantum efficient detector based on n-type silicon photodiodes”, 2017 Metrologia 54 821, which is incorporated by reference herein, describes a Al₂O₃ (Al₂O₃, aluminium oxide)-based induced junction detector.

### SUMMARY OF THE INVENTION

The scope of the invention is defined in the independent claims. Some embodiments are defined in the dependent claims.

According to a first aspect of the present invention, there is provided a radiation detector, comprising:
a substrate made of semiconductor material;
an electric field generating layer on a first face of the substrate;
a first electrical contact on the first face of the substrate and next to the electric field generating layer; and
a second electrical contact on the second face of the substrate and opposite to the electric field generating layer;
   characterized in that the electric field generating layer comprises an inducing electrode;
   and an electrode insulator layer between the substrate and the inducing electrode.

According to a second aspect of the present invention, there is provided a method of manufacturing any one of the radiation detectors disclosed herein. According to further aspects of the second aspect, the manufacturing may comprise single-sided processing or double-sided processing.

### BRIEF DESCRIPTION OF THE DRAWINGS

FIGS. 1A and 1B illustrate sectional or side views of a semiconductor detector device structure in accordance with at least some embodiments;

FIG. 2 illustrates a sectional or side view of a semiconductor detector device structure in accordance with at least some embodiments;

FIG. 3 illustrates a sectional or side view of a semiconductor detector device structure in accordance with at least some embodiments;

FIG. 4 illustrates a sectional or side view of a semiconductor detector device structure in accordance with at least some embodiments;

FIG. 5 illustrates a sectional or side view of a semiconductor detector device structure in accordance with at least some embodiments.

### EMBODIMENTS

The embodiments of the present disclosure provide semiconductor radiation detectors, such as photodetectors, with a low amount of material in the radiation/photon entrance window and minimal doping of semiconductor substrate.

Reference is made to “detector” throughout the description, whereby a semiconductor detector, including any suitable detector, for example: a radiation detector, a photodetector; is meant.

In at least some embodiments, shallow PN junctions can be realized without relying on surface charge layers inside the top dielectric (entrance window), which leads to better reliability, stability and yield and novel tuneability features (as the semiconductor background doping can be selected freely).

The embodiments of the present disclosure require only minimal doping of semiconductor substrate. More specifically, in some embodiments no doping is needed to form the junction, as the junction is formed by an inducing layer. In other words, doping is only used for e.g. front and back contacts and guard contacts, whereby radiation does not pass through doped areas especially on the front side of the detector.

This disclosure describes an induced junction which does not need fixed surface charge to function, and is therefore not bound by the limitations of the surface charge. Depending on the needs of the application, surface charge can be used to enhance the performance in the devices of this disclosure as well.

This disclosure describes embodiments wherein passivation is induced to a silicon surface using an inducing electrode which can be used together with a pin diode device in radiation detection. Additional patterning of the backside of the device enables the current readout without interference from the inducing electrode leakage current.

Improved performance is beneficially achieved by the embodiments described herein. A low or minimal amount of material is present in the entrance window, especially when using graphene, for example when using graphene in the inducing electrode. Further, the formation and strength of PN junction can be controlled by a voltage applied to the inducing electrode in a wide range. Inducing electrode can also be semiconductor layer with high resistivity. Inducing action from the induced charges at the surface of the detecting semiconductor body leads to mutual inducing action increasing the conductivity of the inducing electrode. Improved reliability is achieved in comparison to junctions induced by surface charge, as operation is not affected by loss or gain of surface charge. Finally, new read-out schemes that overcome the limitations of the previous methods, for example when using patterning and guard electrodes on the back side.

Regarding tuneability, a benefit is obtained via the structure of at least some embodiments presented herein, as the charge carrier density induced by the voltage applied to the inducing electrode may be freely chosen by altering the applied voltage. In effect, this allows the control of the characteristics of the PN junction electrically in a wide range even during operation. This allows increasing of the sensitivity and dynamic range of the detector.

The inducing electrode can also comprise several insulating, conducing and/or semiconducting layers, which—in addition to the inducing functionality—together with the dielectric below the electrode form an optically functional stack that enhances the desired detectable absorption of photons inside the active semiconductor layer. Such material stack can form antireflection coating or optical band-pass or band-stop filter. The dielectric can comprise several layers (e.g. Al₂O₃—TiO₂ nanolaminate) to provide further design freedom to maximize the absorption. Some of the layers in the stack can be also patterned to enhance the desired absorption using optically resonant dielectric and plasmonic structures, for example.

In an embodiment, a detector comprises an inducing electrode where bottom layer is some optically ultra-thin conducting or semiconducting layer like graphene and on top there is a patterned metal. In this approach the optically ultra-thin layer serves as uniform inducing electrode. The spectral response properties of the metallic layer are tailored by the geometry of the layer so that the incoming electromagnetic field is maximized in the active semiconductor to maximize the absorption and sensitivity. This design has the beneficial effect of exciting plasmons in the metal layer to assure minimal dissipation in the metal.

In the embodiments of the present disclosure, a detector in accordance with the present disclosure comprises a substrate. The substrate may be made of high resistivity semiconductor material. The substrate may be N- or P-type and have a planar surface, a textured surface or a combination of the two. Suitable semiconductor materials include Silicon, Germanium, III-V semiconductors, II-VI semiconductors (e.g. CdTe).

In the embodiments of the present disclosure, a detector in accordance with the present disclosure comprises an electric field generating layer on a first face of the substrate. The electric field generating layer is used to induce electrons or holes on the silicon surface under the electrode insulator. Such induced charge passivates the surface so that during the operation of the pin-diode, the depletion region will not reach the silicon-dielectric interface which would cause increased leakage current. The induced layer (induced charge layer) operates also as a cathode/anode in the detector.

In some embodiments, a detector in accordance with the present disclosure comprises a first electrical contact on the first face of the substrate and next to the electric field generating layer. The first face can be the so-called front or top face of the substrate.

In some embodiments, a detector in accordance with the present disclosure comprises a second electrical contact on the second face of the substrate and opposite to the electric field generating layer. The second face can be the so-called back or bottom face of the substrate.

In some embodiments, the electric field generating layer may comprise a inducing electrode. The inducing electrode may be formed out of at least one of: graphene, an optically transparent conductor, e.g. indium tin oxide (ITO), thin TiN, Aluminum or other metal (e.g. for high energy X-ray and gamma ray application), semimetal, semiconductor (for induced junction—inducing electrode inter-induction). The electrode may comprise a patterned layer, or multiple patterned layers. In some embodiments, the layers may be of different materials. In some embodiments, the inducing electrode may comprise a 2D material, whereby the term 2D material refers to a crystalline solid consisting or comprising of a single layer of atoms. 2D materials include graphene, graphyne, borophene, silicene, antimonene.

In the embodiments of the present disclosure, the electric field generating layer comprises an electrode insulator layer between the substrate and the inducing electrode. The electrode insulator layer may be formed out of at least one of Al₂O₃ (e.g. ALD), SiO₂ (e.g. thermal, LPCVD TEOS SiO₂, PECVD SiO₂, ALD SiO₂). A ferroelectric, ferroelectret, and/or electret material may also be used for the electrode insulator layer. Suitable materials include ScAlN (Scandium-doped aluminium nitride), HfZrO (hafnium zirconium oxide) and ferroelectret materials (including polymer foams which may consist of cellular polymer structure filled with air, for example the polymer may be polypropylene), and electret materials. An electret is a dielectric material that has a quasi-permanent electric charge or dipole polarisation. For example, a stack of silicon oxide and silicon nitride can be turned into a stable electret by charging the surface with a corona charge and annealing the layer afterwards. Charged electrets may also be produced by first heating the electret material and then cooling it in presence of strong electric field. This inducing charge is stable for decades or more. In addition, polymer materials can be used. Examples of suitable electret materials may comprise polymers (including fluoropolymers such as PTFE), or e.g. a stack of silicon oxide and silicon nitride.). A benefit of using an electret material is, in addition to the exhibition of electric polarization, the ability to retain a static surface and/or volume charge of one or two polarities.

A benefit of using a ferroelectric, ferroelectret, and/or electret material is the ability to choose the polarity of the inducing charge by controlling the direction of the polarization during fabrication. Further, typical SiO₂- or Al₂O₃-based implementations allow increasing the charge only based on deposition and heat treatment, whereby it is challenging to increase the inducing charge using only these limited methods. However, when using ferroelectric, ferroelectret, and/or electret materials, the charge can be controlled in an improved manner, as the charge may be controlled using an external electrical field and/or charge during the manufacturing process in addition to the deposition and/or heat treatment. In addition, use of the above-mentioned materials provides a range of options when considering radiation absorption, charge duration, charge stability, heat resistance, suitability for manufacturing process.

In some embodiments, a detector in accordance with the present disclosure comprises a floating electrode structure, where secondary electrode or inputs are deposited above or below the inducing electrode and are electrically isolated from it. These inputs are only capacitively connected to the inducing electrode, since the inducing electrode is completely surrounded by highly resistive material. So, in terms of its DC operating point, the inducing electrode is a floating node.

In some embodiments, a detector in accordance with the present disclosure comprises one or more guard rails. Guard rails may be used to collect the current originating outside of the diode area.

In some embodiments, a detector in accordance with the present disclosure comprises a substrate having a resistivity value of 0.5 kΩcm or higher. For silicon, very good values are 10 kΩcm or higher.

In some embodiments, a detector in accordance with the present disclosure comprises at least one dopant, said dopant comprising at least one of the following materials: boron, aluminium, gallium, indium, phosphorus, arsenic, antimony, bismuth, lithium, silicon, germanium, nitrogen, gold, platinum, tellurium, sulphur, tin, beryllium, zinc, chromium, carbon, selenium, magnesium, chlorine, iodine, fluorine. The front contact and guard doping should be N-type doping if the substrate is P-type, and P-type doping if substrate is N-type. For the back contact and guard doping: P-type doping, if substrate is P-type and N-type doping if substrate is N-type.

In some embodiments, a detector in accordance with the present disclosure comprises or consists of an undoped substrate, which does not contain intentionally added impurities. Such a substrate may comprise or consist of pure semiconductor crystal, or a semiconductor crystal with naturally occurring doping originating from crystallographic defects such as vacancies.

In some embodiments, a detector in accordance with the present disclosure comprises a first contact comprising a well and doping. Said first contact may be located around the electrode insulator. In an embodiment, the first electrical contact surrounds the electrode insulator layer.

In some embodiments, the thickness of the substrate of the detector is from 200 nm to 50 mm, preferably from 1 μm to 5000 μm.

In some embodiments, a detector in accordance with the present disclosure comprises polarization of the electrode insulator, for example the electrode insulator may comprise a ferroelectric, ferroelectret, and/or electret material and an inducing electrode may be placed on top of it. This provides the benefit of controlling the charge in an improved manner, i.e. the polarization or “programming” of the layer may be done by applying a voltage pulse to the inducing electrode. This allows the charge and thereby the characteristics of the PN junction to be changed electrically during operation. In particular, a beneficial embodiment is where the electrode insulator comprises a ferroelectric material.

In some embodiments, a detector in accordance with the present disclosure is configured so that an electric field induced inversion layer is induced by the inducing electrode under the electrode insulator. When using a P-type substrate, this means that electrons appear in a very thin layer at the semiconductor-oxide interface, called an inversion layer because they are oppositely charged to the holes that prevail in the P-type material. In an N-type substrate, the inversion layer is formed in a similar way by holes. When an inversion layer forms, the depletion width ceases to expand with increase in the induced charge Q.

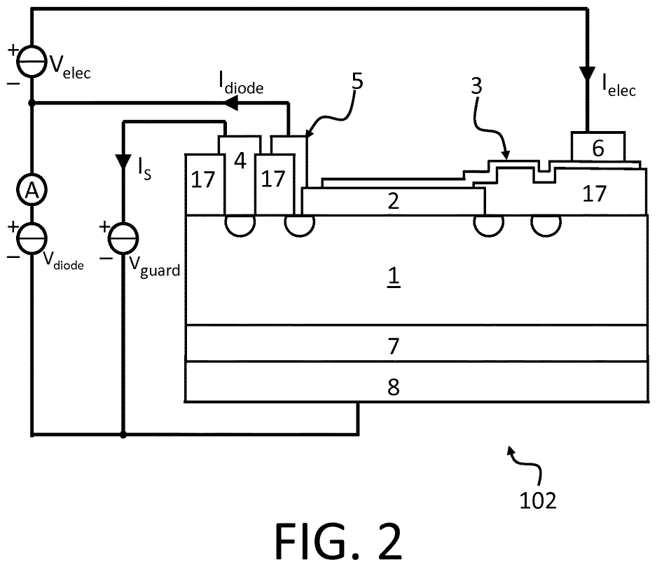

In a first exemplary embodiment, graphene is used as the inducing material and Al₂O₃(Al₂O₃) as the electrode insulator material. A schematic representation of the device is shown in FIG. 2.

In the first exemplary embodiment, the inducing electrode is used to induce electrons or holes on the silicon surface under the electrode insulator. Such induced charge passivates the surface so that during the operation of the pin-diode, the depletion region will not reach the silicon-dielectric interface which would cause increased leakage current. The induced layer operates also as a cathode/anode in the detector.

The leakage current I_{elec} from the inducing electrode to the front contact of the diode will affect the total current. This additional current is not added to the current measured from the back contact. The backside patterning and current readout from the back contact is used to solve the inducing electrode leakage current issue in the front contact. Component of the useful photocurrent can also flow to the inducing electrode in some cases.

Guard rings are used to collect the current originating outside of the diode area.

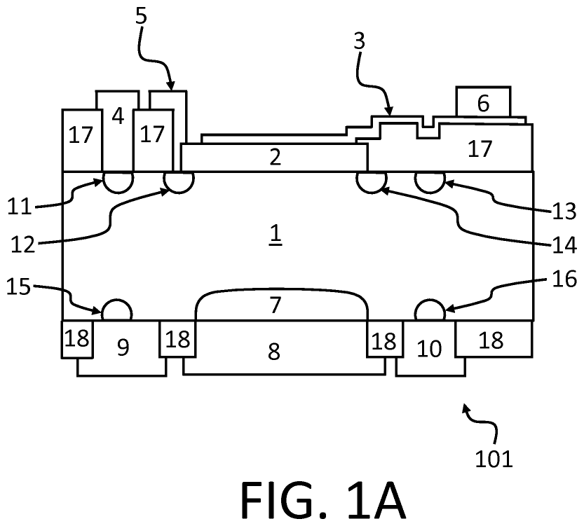

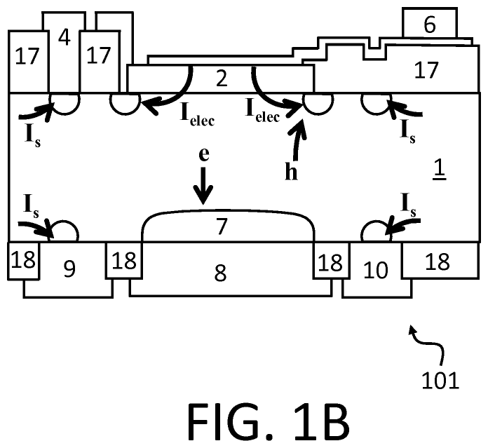

FIG. 1A illustrates a cross-section view of exemplary embodiment of a detector 101 in accordance with at least some embodiments of the present invention. The detector 101 comprises a substrate 1, an electrode insulator 2, a inducing electrode 3, a front guard contact (FGC) 4, a front contact 5, a contact to the inducing electrode 6, back contact doping 7, back contact 8, back guard contact (BGC) 9, and back guard contact 10. In addition, the detector 101 may comprise front guard doping (FGD) 11 and 13, front contact doping (FCD) 12 and 14, and back guard doping (BGD) 15 and 16.

FIG. 1B illustrates a cross-section view of exemplary embodiment of the detector 101, where the flow of substrate and inducing electrode currents as well as electron holes have been illustrated in the case where the substrate is P-type, front contact doping is N-type, and the back contact doping is P-type. The front and back guards collect the substrate parasitic currents.

With respect to the terms used in the Figures, i.e. e, h, Iₛ, I_{elec} etc., e is electron, h is hole, Iₛ is parasitic current from the semiconductor substrate, collected by the guard electrodes and I_{elec} is leakage current from inducing electrode to the front contact. V_{elec} is the electrode voltage, V_{diode} is the voltage applied across the PN junction. V_{guard} is the voltage applied to the guard electrode.

FIG. 2 illustrates a cross-section view of exemplary embodiment of a semiconductor detector 102 based on electrode induced junction fabricated by single-sided processing, in accordance with at least some embodiments of the present invention. Detector 102 is shown with P-type substrate, where front contact doping is N-type, and back contact doping P-type.

If leakage current I_{elec} is present, then the measured diode output current must be corrected by the formula I_{corr diode}=I_{diode}−I_{elec}. The corrected current I_{corr diode} represents the radiation induced current, which flows between the back contact 8 and front contact 5 through the back contact doping 7, a portion of the substrate 1 and the front contact doping 12, 14. The portion of the substrate 1 comprises the electric field induced inversion layer (not shown) induced by the electric field generating layer 2, 3 in a surface layer of the substrate 1 under the electrode insulator 2. The portion of the substrate 1 further comprises the volume of the substrate 1 between the electric field induced inversion layer and the back contact doping 7, which volume comprises the depletion region.

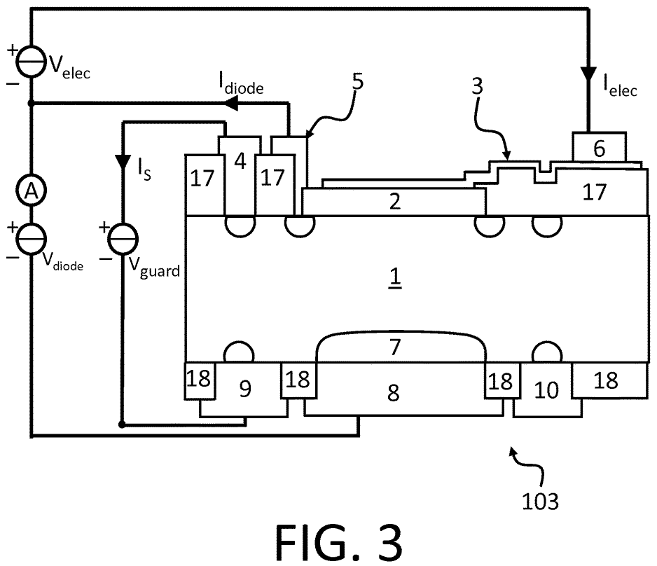

FIG. 3 illustrates a cross-section view of exemplary embodiment of a detector 103 in accordance with at least some embodiments of the present invention. The semiconductor detector 103 is based on induced junction fabricated by double-sided processing. Detector 103 comprises a P-type substrate 1, where front contact doping is N-type, and back contact doping is P-type. The diode current measured from the back contact 8 is not affected by the leakage current I_{elec}.

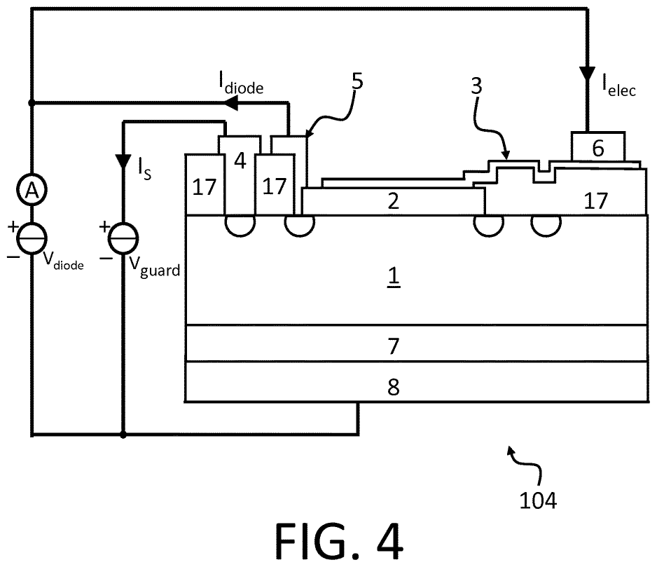

FIG. 4 illustrates a cross-section view of exemplary embodiment of a detector 104 in accordance with at least some embodiments of the present invention. The semiconductor detector 104 is based on electrode work-function induced junction, fabricated by single-sided processing. The detector comprises a P-type substrate, where the front contact doping is N-type, and back contact doping P-type. If leakage current I_{elec} is present, then it contributes to the measured diode output current, and the inducing electrode functions as an additional current collector.

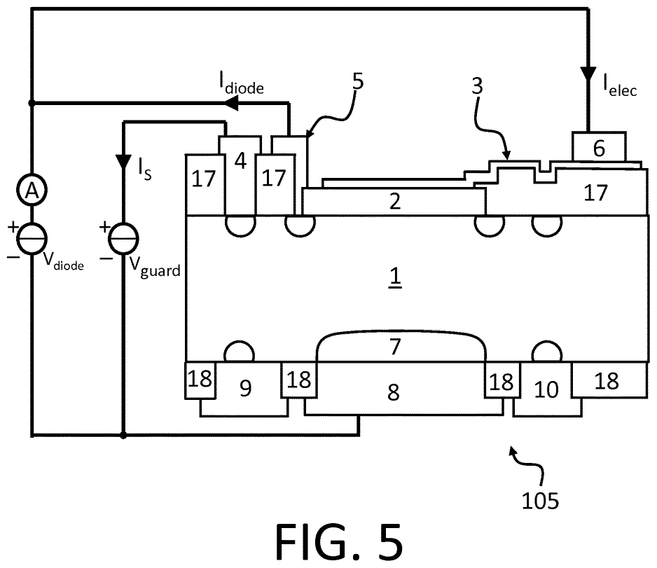

FIG. 5 illustrates a cross-section view of exemplary embodiment of a detector 105 in accordance with at least some embodiments of the present invention. The semiconductor detector 105 is based on electrode work-function induced junction fabricated by double-sided processing. A difference in work functions of the substrate surface and the inducing electrode material acts as effective inducing voltage. Detector 105 comprises a P-type substrate, where the front contact doping is N-type, and back contact doping P-type. The diode current measured from the back contact is not affected by the leakage current I_{elec}.

In a further embodiment, the detector has an N-type substrate, whereby the back contact is n-type, and the front contact is p-type.

In a further embodiment, otherwise like the detector of FIG. 5, the front contact 5 and contact 6 are electrically connected by combining these layers structurally during the manufacturing process. This has the beneficial effect of a more stable construction and a simpler manufacturing process, as there is no need to make a connection in a circuit which is not part of the detector.

The present disclosure is suitable for use in and finds industrial applicability in at least the following: photodetectors in all spectral ranges: single pixels and imaging array (vast amount of applications from cameras to light level sensors etc.), detection of UV: Solar blind UV detectors, Military applications: detecting a flash from the firing of a weapon or explosive, X-rays: Wide range of medical applications: Computer tomography (CT), dental X-ray, etc., material analysis, structural monitoring, X-ray customs inspections (i.e. non-intrusive inspections). Further, at least some embodiments are sensitive to radiation such as alpha, beta, gamma radiation, and particle radiation, which is beneficial for safety and monitoring applications.

The following combinations of materials may be employed in construction of the detectors disclosed herein, including the detectors shown in the Figures. A single combination of materials is disclosed on a single row:

| Detector | | Electrode | Inducing |
|---|---|---|---|
| embodiment | Substrate | insulator | electrode |
| 1 | N-type silicon | Al₂O₃ | Graphene |
| 2 | N-type silicon | SiO₂ | Graphene |
| 3 | N-type silicon | Al₂O₃ | Indium |
| | | | tin oxide |
| 4 | N-type silicon | SiO₂ | Indium |
| | | | tin oxide |
| 5 | N-type silicon | Al₂O₃ | Aluminum |
| 6 | N-type silicon | SiO₂ | Aluminum |
| 7 | N-type silicon | ZrHfO | Graphene |
| 8 | N-type silicon | ZrHfO | Indium |
| | | | tin oxide |
| 9 | N-type silicon | ZrHfO | Aluminum |
| 10 | N-type silicon | (Pb, La)(Zr, Ti)O₃ | Graphene |
| 11 | N-type silicon | (Pb, La)(Zr, Ti)O₃ | Indium |
| | | | tin oxide |
| 12 | N-type silicon | (Pb, La)(Zr, Ti)O₃ | Aluminum |
| 13 | P-type silicon | SiO₂ | Graphene |
| 14 | P-type silicon | SiO₂ | Indium |
| | | | tin oxide |
| 15 | P-type silicon | SiO₂ | Aluminum |
| 16 | P-type silicon | ZrHfO | Graphene |
| 17 | P-type silicon | ZrHfO | Indium |
| | | | tin oxide |
| 18 | P-type silicon | ZrHfO | Aluminum |
| 19 | P-type silicon | (Pb, La)(Zr, Ti)O₃ | Graphene |
| 20 | P-type silicon | (Pb, La)(Zr, Ti)O₃ | Indium |
| | | | tin oxide |
| 21 | P-type silicon | (Pb, La)(Zr, Ti)O₃ | Aluminum |
| 22 | N-type germanium | Al₂O₃ | Graphene |
| 23 | N-type germanium | SiO₂ | Graphene |
| 24 | N-type germanium | Al₂O₃ | Indium |
| | | | tin oxide |
| 25 | N-type germanium | SiO₂ | Indium |
| | | | tin oxide |
| 26 | N-type germanium | Al₂O₃ | Aluminum |
| 27 | N-type germanium | SiO₂ | Aluminum |
| 28 | N-type germanium | ZrHfO | Graphene |
| 29 | N-type germanium | ZrHfO | Indium |
| | | | tin oxide |
| 30 | N-type germanium | ZrHfO | Aluminum |
| 31 | N-type germanium | (Pb, La)(Zr, Ti)O₃ | Graphene |
| 32 | N-type germanium | (Pb, La)(Zr, Ti)O₃ | Indium |
| | | | tin oxide |
| 33 | N-type germanium | (Pb, La)(Zr, Ti)O₃ | Aluminum |
| 34 | P-type germanium | SiO₂ | Graphene |
| 35 | P-type germanium | SiO₂ | Indium |
| | | | tin oxide |
| 36 | P-type germanium | SiO₂ | Aluminum |
| 37 | P-type germanium | ZrHfO | Graphene |
| 38 | P-type germanium | ZrHfO | Indium |
| | | | tin oxide |
| 39 | P-type germanium | ZrHfO | Aluminum |
| 40 | P-type germanium | (Pb, La)(Zr, Ti)O₃ | Graphene |
| 41 | P-type germanium | (Pb, La)(Zr, Ti)O₃ | Indium |
| | | | tin oxide |
| 42 | P-type germanium | (Pb, La)(Zr, Ti)O₃ | Aluminum |

In the above embodiments 1-42, for example, the following dopants and contact metals may be used: substrate dopants in N-type silicon and germanium may comprise elements such as phosphorus, arsenic or antimony. Substrate dopants in P-type silicon and germanium may comprise elements such as boron and aluminum. The front and back dielectric may comprise SiO₂. Front contact metal, front guard contact metal, inducing electrode contact metal, back contact metal, and back guard contact metal may comprise metals such as aluminum, gold, titanium, wolfram, nickel, copper, molybdenum. The format (Pb,La)(Zr,Ti)O₃ is intended to mean PbZrO₃, PbTiO₃, LaZrO₃, or LaTiO₃.

In some embodiments, the substrate of the detector comprises dopants such that the dopant concentration is less than 10¹⁵ dopant atoms per cm³, such as less than 10¹¹ dopant atoms per cm³, for example less than 10⁹ dopant atoms per cm³.

It is to be understood that the embodiments of the invention disclosed are not limited to the particular structures, process steps, or materials disclosed herein, but are extended to equivalents thereof as would be recognized by those ordinarily skilled in the relevant arts. It should also be understood that terminology employed herein is used for the purpose of describing particular embodiments only and is not intended to be limiting.

Reference throughout this specification to one embodiment or an embodiment means that a particular feature, structure, or characteristic described in connection with the embodiment is included in at least one embodiment of the present invention. Thus, appearances of the phrases “in one embodiment” or “in an embodiment” in various places throughout this specification are not necessarily all referring to the same embodiment. Where reference is made to a numerical value using a term such as, for example, about or substantially, the exact numerical value is also disclosed.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary. In addition, various embodiments and example of the present invention may be referred to herein along with alternatives for the various components thereof. It is understood that such embodiments, examples, and alternatives are not to be construed as de facto equivalents of one another, but are to be considered as separate and autonomous representations of the present invention.

Furthermore, the described features, structures, or characteristics may be combined in any suitable manner in one or more embodiments. In the preceding description, numerous specific details are provided, such as examples of lengths, widths, shapes, etc., to provide a thorough understanding of embodiments of the invention. One skilled in the relevant art will recognize, however, that the invention can be practiced without one or more of the specific details, or with other methods, components, materials, etc. In other instances, well-known structures, materials, or operations are not shown or described in detail to avoid obscuring aspects of the invention.

While the forgoing examples are illustrative of the principles of the present invention in one or more particular applications, it will be apparent to those of ordinary skill in the art that numerous modifications in form, usage and details of implementation can be made without the exercise of inventive faculty, and without departing from the principles and concepts of the invention. Accordingly, it is not intended that the invention be limited, except as by the claims set forth below.

The verbs “to comprise” and “to include” are used in this document as open limitations that neither exclude nor require the existence of also un-recited features. The features recited in depending claims are mutually freely combinable unless otherwise explicitly stated. Furthermore, it is to be understood that the use of “a” or “an”, that is, a singular form, throughout this document does not exclude a plurality.

### REFERENCE SIGNS LIST

| | |
|---|---|
| 101, 102, 103, | Detector |
| 104, 105 | |
| 1 | Substrate |
| 2 | Electrode insulator |
| 3 | Inducing electrode |
| 4 | Front guard contact |
| 5 | Front contact |
| 6 | Contact to inducing electrode |
| 7 | Back contact doping |
| 8 | Back contact |
| 9, 10 | Back guard contact |
| 11, 13 | Front guard doping |
| 12, 14 | Front contact doping |
| 15, 16 | Back guard doping |
| 17 | Front dielectric |
| 18 | Back dielectric |

1. A radiation detector, comprising:
a substrate made of semiconductor material;
an electric field generating layer on a first face of the substrate;
a first electrical contact on the first face of the substrate and next to the electric field generating layer; and
a second electrical contact on the second face of the substrate and opposite to the electric field generating layer;
wherein the electric field generating layer comprises:
an inducing electrode; and
an electrode insulator layer between the substrate and the inducing electrode.

2. The radiation detector of claim 1, wherein:
the inducing electrode comprises graphene.

3. (canceled)

4. The radiation detector of claim 1, wherein:
the electrode insulator layer comprises at least one of: Al2O3, SiO2.

5. The radiation detector of claim 1, wherein:
the inducing electrode comprises a plurality of layers.

6. The radiation detector of claim 5, wherein:
the plurality of layers, together with the electrode insulator layer below the inducing electrode, forms at least one of: an antireflection coating, an optical band-pass, and/or a band-stop filter.

7. The radiation detector of claim 1, wherein:
the resistivity of the substrate is more than 10 kΩcm.

8. The radiation detector of claim 1, wherein:
the substrate comprises at least one of the following: Silicon, Germanium, III-V semiconductor, and/or II-VI semiconductor.

9. (canceled)

10. The radiation detector of claim 1, wherein:
the first electrical contact is located around the electrode insulator.

11. (canceled)

12. The radiation detector of claim 1, wherein:
the electrode insulator layer comprises at least one of a ferroelectric, ferroelectret, and/or electret material.

13. The radiation detector of claim 1, wherein:
the detector is configured so that an electric field induced inversion layer is formed under the electrode insulator.

14. The radiation detector of claim 1, wherein:
the first electrical contact comprises contact doping in the substrate.

15. The radiation detector of claim 13, wherein:
the first electrical contact comprises a front contact doping well in the substrates; and
the detector is configured so that a current flow path is formed between the electric field induced inversion layer and the front contact doping well for conducting the radiation induced current.

16. The radiation detector of claim 1, wherein:
the first electrical contact is located around the electrode insulator layer.

17. The radiation detector of claim 1, wherein:
the detector is configured so that a PN junction is induced in the substrate by the electric field generating layer.

18.-22. (canceled)

23. The radiation detector of claim 1, wherein:
the detector is configured to received detected radiation through a radiation entrance window, the radiation entrance window comprising at least a portion of the electrode insulator layer.

24. The radiation detector of claim 1, further comprising:
a photodiode having an induced PN junction, a diode voltage of the photodiode being between the first electrical contact and the second electrical contact and across the induced PN junction.

25. The radiation detector of claim 1, wherein the detector is configured so that a radiation induced current flows along a current flow path between the second electrical contact and the first electrical contact, the current flow path comprising:
a contact doping of the second electrical contact;
a portion of the substrate; and
a contact doping of the first electrical contact.

26. The radiation detector of claim 25, wherein said portion of the substrate comprises:
the electric field induced inversion layer induced by the electric field generating layer in a surface layer of the substrate under the electrode insulator; and
a volume of the substrate between the electric field induced inversion layer and the contact doping of the second electrical contact, which volume comprises a depletion region.

27. A radiation detector, comprising:
a substrate made of semiconductor material;
an electric field generating layer on a first face of the substrate, the electric field generating layer comprising an inducing electrode and an electrode insulator layer between the substrate and the inducing electrode;
a first electrical contact on the first face of the substrate and next to the electric field generating layer; and
a second electrical contact on the second face of the substrate and opposite to the electric field generating layer,
wherein the detector is configured to receive radiation through a radiation entrance window, the radiation entrance window comprising at least a portion of the electrode insulator layer; and
wherein the detector is configured to, in response to the received radiation, cause a radiation induced current flow along a current flow path between the second electrical contact and the first electrical contact through a portion of the substrate.

28. The radiation detector of claim 27, wherein the portion of the substrate comprises:
the electric field induced inversion layer induced by the electric field generating layer in a surface layer of the substrate under the electrode insulator; and
a volume of the substrate between the electric field induced inversion layer and the second electrical contact, which volume comprises a depletion region.
